(19) United States
(12) Patent Application Publication
(10) Pub. No.: US 2024/0352181 A1
(43) Pub. Date: Oct. 24, 2024

(54) COMPOSITION

(71) Applicant: Merck Patent GmbH, Darmstadt (DE)

(72) Inventors: Pawel MISKIEWICZ, Darmstadt (DE); Manuel HAMBURGER, Darmstadt (DE); Hyun-Jin YOON, Pyeongtaek (KR)

(21) Appl. No.: 18/687,336

(22) PCT Filed: Aug. 29, 2022
(86) PCT No.: PCT/EP2022/073871

§ 371 Date: Feb. 28, 2024

(30) Foreign Application Priority Data
Aug. 31, 2021 (EP) 21193975.6

(51) Int. Cl. C08G 61/08; C08K 5/18; C09D 165/00

(52) U.S. Cl. CPC C08G 61/08; C09D 165/00; C08G 2261/11; C08G 2261/1412; C08G 2261/146; C08G 2261/148; C08G 2261/20; C08G 2261/3324; C08G 2261/418; C08G 2261/95; C08K 5/18

(57) ABSTRACT

The present application relates to a composition comprising some components; using thereof; manufacturing a layer; and manufacturing an electronic device.

### TECHNICAL FIELD

The present application relates to a composition comprising (a) monomers, (b) a metal catalyst, (c) a compound capable of releasing a Bronsted acid and (d) an absorber; using thereof; manufacturing a polycycloolefin layer; and manufacturing an electronic device.

### BACKGROUND

Electronic devices, and particularly organic electronic devices, have become thinner and thinner over the years, thereby now allowing for devices that can be rolled or bent. This development has led to the development and recent market introduction of, for example, smartphones with foldable displays based on organic light emitting device technology.

However, such devices are sensitive to environmental influences, especially to oxygen and moisture. If not protected, their performance will degrade over time, in some instances even rather quickly.

Additionally, the mechanical stresses induced by folding and bending may also lead to fractures in any of the device layers directly in or in proximity to the fold or bend.

Under such circumstance, several trials are done as following Patent documents.
In Patent document 1, certain cycloolefin monomers are studied to make layers to obtain improved optical property.
In Patent document 2, Compositions having certain latent catalyst and compound capable of generating a Bronsted acid are studied as suitable ink composition for 3D object.
In Patent document 3, a single component composition which is able to undergo mass polymerization under the OLED device fabrication conditions is provided. Moreover, a composition having certain cycloolefin monomer, catalyst and a compound capable of releasing a Bronsted acid is studied.
In Patent document 4, a stable single component mass polymerizable composition is provided, which shows no change in viscosity at or below normal storage conditions, but which undergoes mass polymerization only under the process conditions where an OLED device is finally fabricated, such as, for example, by the use of radiation and/or thermal process.
In Patent document 5, polycycloolefin polymer is studied to be used in organic electronic device, which can possess low dielectric property.

### PRIOR ART DOCUMENTS

[Patent document 1] WO2020/002277 A1
[Patent document 2] US2020/002466 A1
[Patent document 3] US 2019/0232267 A1
[Patent document 4] US2019/048130 A1
[Patent document 5] WO2015/135622 A1

### SUMMARY

### Problems to be Solved by the Invention

The present inventors considered that one or more technical problems still need to be improved.

Examples of these include the followings: to obtain a polycycloolefin layer transparent in visible wavelength; to obtain a polycycloolefin layer which blocks invisible wavelength; to use narrower wavelength exposure to cure the layer, though an absorber absorbs certain light; to obtain a polycycloolefin layer to protect an underlayer or underlying base member from damage; to obtain a polycycloolefin layer with good permittivity or useful for encapsulation layer or insulation layer; to obtain a polycycloolefin layer with good flexibility or useful for flexible display device; to obtain a clear composition with good solubility of solute; to obtain a stable composition (e.g., capable of avoiding turbid); to obtain a composition with good processability by printing or coating; to obtain a composition with good wettability even on a wide substrate; and/or to obtain a smooth, homogenous, closed or pinhole-free polycycloolefin layer.

### Means for Solving the Problems

The present application provides a composition comprising (a) one or more monomers of formula (I); (b) a latent organo-transition metal catalyst comprising a metal selected from the group consisting of ruthenium, osmium or palladium; (c) a compound capable of releasing a Bronsted acid when subjected to photolytic conditions; and (d) an absorber compound having a maximum absorption wavelength between 280-410 nm;
wherein the formula (I) is represented by below formula.

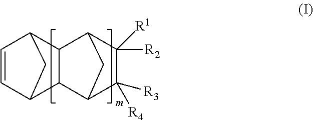

Detailed descriptions of each elements follow.

Also, the present application provides a method of manufacturing a polycycloolefin layer comprising steps of; (1) preparing a base member; (2) applying the composition according to this invention above the base member; and (3) polymerizing the (a) monomers in the composition.

As another embodiment, the present application provides a method of manufacturing an electronic device comprising a method of manufacturing a polycycloolefin layer of this invention. As one another aspect of this invention, the present application also provides an electronic device manufactured by the method of this invention.

### Effects of the Invention

Using the composition and/or the method according to the present invention, it is possible to expect one or more of the following effects.

It is possible to obtain a polycycloolefin layer transparent in visible wavelength. It is possible to obtain a polycycloolefin layer which blocks invisible wavelength (e.g., the area of narrower wavelength; UV wavelength).

It is possible to use narrower wavelength (e.g., UV) exposure to cure the layer, though (d) absorber has absorption around this wavelength. It is possible to obtain a polycycloolefin layer to protect an underlayer or underlying base member from damage caused by narrower wavelength exposure (e.g., UV). It is possible to obtain a polycycloolefin layer to protect an underlayer or underlying base member from water, oxygen, or dust. It is possible to obtain a polycycloolefin layer which exhibits good permittivity and can be useful for encapsulation layer or insulation layer. It is possible to obtain a polycycloolefin layer which exhibit good flexibility and can be useful for flexible display device. It is possible to obtain a clear composition in which solubility of solute is good. It is possible to obtain a stable composition which can avoid turbid. It is possible to obtain a composition which can exhibit good processability by printing or coating. It is possible to obtain a composition which can exhibit good wettability even on a wide substrate (e.g., in a display device). It is possible to obtain a smooth, homogenous, closed or pinhole-free polycycloolefin layer.

### DETAILED DESCRIPTION

Embodiments of the present invention are described below in detail.

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, the compound itself that generates a base). An aspect in which the compound is dissolved or dispersed in a solvent and added to the composition is also possible. As one embodiment of the present invention, it is preferable that such a solvent is contained in the composition of this invention as a solvent of additive.

In general terms, the present application relates to a composition comprising (a) a monomer(s), (b) a metal catalyst, (c) a compound capable to release a Bronsted acid, and (d) an absorber. It is noted that for the purposes of the present application the terms “cycloolefin” and “polycycloolefin” can be preferably each denoted as “norbornene” and “polynorbornene”.

### [Composition]

Present invention provides a composition comprising (a) one or more monomers of formula (I); (b) a latent organo-transition metal catalyst comprising a metal selected from the group consisting of ruthenium, osmium or palladium; (c) a compound capable of releasing a Bronsted acid when subjected to photolytic conditions; and (d) an absorber compound having a maximum absorption wavelength between 280-410 nm. The composition can be preferably a polycycloolefin layer forming composition (more preferably a polycycloolefin layer forming composition transparent of visible light). A polycycloolefin layer forming composition can consist of the composition according to the present invention. Each component is followingly described in detail.

The viscosity of the composition of this invention can be preferably 5-20 mPass (more preferably 5-15 mPass; further preferably 5-12 mPass). The viscosity can be measured by known method. The temperature to measure a viscosity of the composition of this invention can be preferably 20-40° C. (more preferably 25-40° C.; further preferably at 40° C.)

The surface tension of the composition of this invention can be preferably 10-50 mN/m (more preferably 20-40 mN/m; further preferably 25-40 mN/m) at 25° C. The surface tension can be measured by known method. Without wishing to be bound by theory, the composition of this invention can exhibit good processability by printing and coating techniques, good wetting on a wide range of substrate materials and/or enable to obtain smooth, homogenous, closed and/or pinhole-free films when applied to a base member.

[(a) monomer]

The composition of the present invention comprises (a) one or more monomers of formula (I); wherein the formula (I) is represented by below formula.

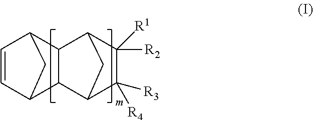

m is an integer 0, 1 or 2 (preferably 0 or 1). As one preferable embodiment of this invention, m is 1. As another preferable embodiment of this invention, m is 0.
R₁, R₂, R₃ and R₄ are each independently selected from the group consisting of hydrogen, halogen, methyl, ethyl, linear or branched C₁₋₂₀ alkyl, perfluoro C₁₋₁₂ alkyl, hydroxy C₁₋₁₆ alkyl, C₃₋₁₂ cycloalkyl, C₆₋₁₂ bicycloalkyl, (CH₂)ₐ—C₆₋₁₂ bicycloalkenyl, C₇₋₁₄ tricycloalkyl, substituted or unsubstituted C₆₋₁₀ aryl, substituted or unsubstituted C₆₋₁₀ aryl C₁₋₆ alkyl, perfluoro C₆₋₁₀ aryl, perfluoro C₆₋₁₀ aryl C₁₋₃ alkyl and a group of formula (A):

—Z-Aryl (A).
R₁, R₂, R₃ and R₄ are each independently preferably selected from the group consisting of hydrogen, ethyl, linear or branched C₃₋₈ alkyl, substituted or unsubstituted C₆₋₁₀ aryl C₁₋₆ alkyl, and a group of formula (A); more preferably selected from the group consisting of hydrogen, ethyl, linear or branched C₃₋₈ alkyl, and unsubstituted C₆₋₁₀ aryl C₁₋₆ alkyl.

As one preferred embodiment of this invention R₂, R₃ and R₄ are hydrogen. As one preferred embodiment of this invention R₁ is not hydrogen.
Z is a single bond or a group selected from the group consisting of: (CR₅R₆)ₐ, O(CR₅R₆)ₐ, (CR₅R₆)ₐO, (CR₅R₆)ₐ—O—(CR₅R₆)_{b}, (CR₅R₆)ₐ—O—(SiR₅R₆)_{b}, (CR₅R₆)ₐ—(CO)O—(CR₅R₆)_{b}. Z is preferably (CR₅R₆)ₐ.
a and b are integers each independently is 1 to 12 (preferably 1 to 3; more preferably 1 or 2; further preferably 2).
R₅ and R₆ are each independently selected from the group consisting of hydrogen, methyl, ethyl, linear or branched C₃₋₆ alkyl, hydroxy, methoxy, ethoxy, linear or branched C₃₋₆ alkyloxy, acetoxy, C₂₋₆ acyl, hydroxymethyl, hydroxyethyl, linear or branched hydroxy C₃₋₆ alkyl, substituted or unsubstituted phenyl and substituted or unsubstituted phenoxy (preferably selected from the group consisting of hydrogen, methyl, and t-butyl; more preferably hydrogen).

Aryl is phenyl or phenyl substituted with one or more of groups selected from the group consisting of methyl, ethyl, linear or branched C₃₋₆ alkyl, hydroxy, methoxy, ethoxy, linear or branched C₃₋₆ alkyloxy, acetoxy, C₂₋₆ acyl, hydroxymethyl, hydroxyethyl, linear or branched hydroxy C₃₋₆ alkyl, phenyl and phenoxy; preferably phenyl.

Optionally one of R₁ or R₂ taken together with one of R₃ or R₄ and the carbon atoms to which they are attached to form a C₅₋₇ carbocyclic ring optionally containing one or more double bonds. It is also one good embodiment that none of R₁ or R₂ taken together with any of R₃ or R₄ to form a C₅₋₇ carbocyclic ring.

As one embodiment of this invention, formula (I) can be formula (I-a).

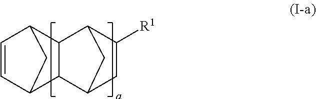

a is 0 or 1. As one of the embodiments, a is 0. As another embodiment, a is 1.
R₁ is a linear or branched C₁₋₂₀ alkyl group or an unsubstituted C₆₋₁₀ aryl C₁₋₆ alkyl (preferably methyl, ethyl, isopropyl, t-butyl, n-butyl, n-hexyl, n-octyl phenylmethyl or phenethyl; more preferably n-butyl, n-hexyl, n-octyl or phenethyl).

As preferred embodiments, formula (I) can be selected from the group consisting of the following formula (I-a-01) to (I-a-21):

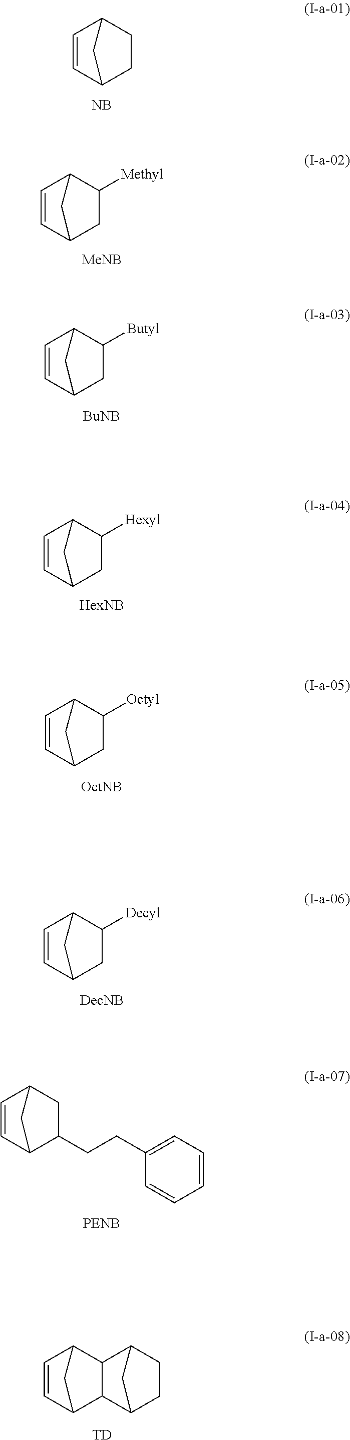

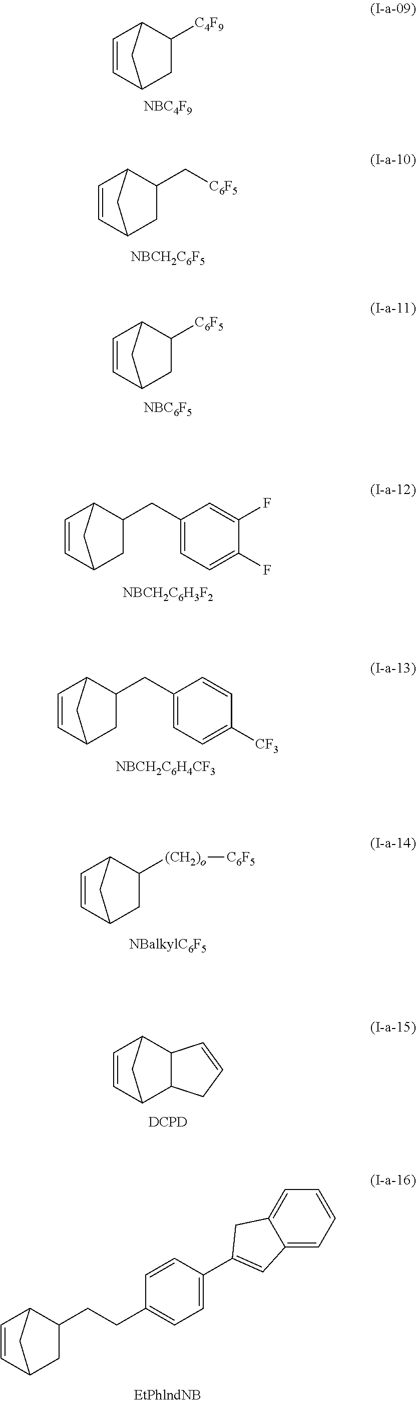

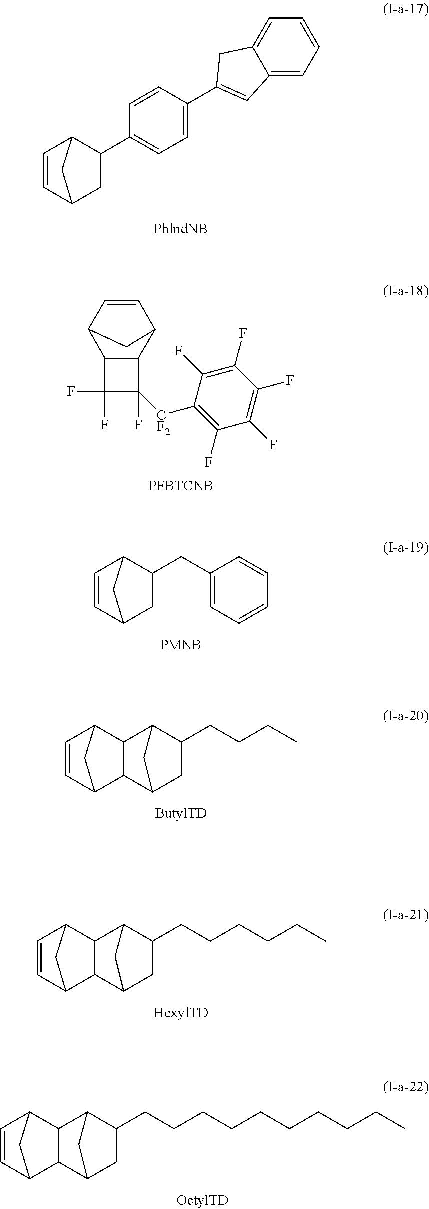

As more preferred embodiments, formula (I) can be selected from the group consisting of the above formula (I-a-04), (I-a-05), (I-a-07), (I-a-08), (I-a-19), (I-a-20), (I-a-21) and (I-a-22). As further preferred embodiments, formula (I) can be selected from the group consisting of the above formula (I-a-04), (I-a-07), (I-a-08), (I-a-20), and (I-a-21).

As one embodiment of the composition of this invention, the content of the (a) monomer is 80-99.99 mass % (preferably 90-99.99 mass %; more preferably 90-99.95 mass %) based on the composition.

As (a) monomer, mixture of isomers each represented by formula (I) is accepted in this invention.

### [(b) Metal Catalyst]

The composition of the invention comprises (b) a latent organo-transition metal catalyst comprising a metal selected from the group consisting of ruthenium, osmium, or palladium. The metal is preferably ruthenium or osmium (more preferably ruthenium).

The latent organo-transition metal catalyst can be an organo-ruthenium compound selected from the group consisting of a compound of formula (IIA), a compound of formula (IIB), a compound of formula (IIIA), a compound of formula (IIIB), a compound of formula (IIIC), and a compound of formula (IIID).

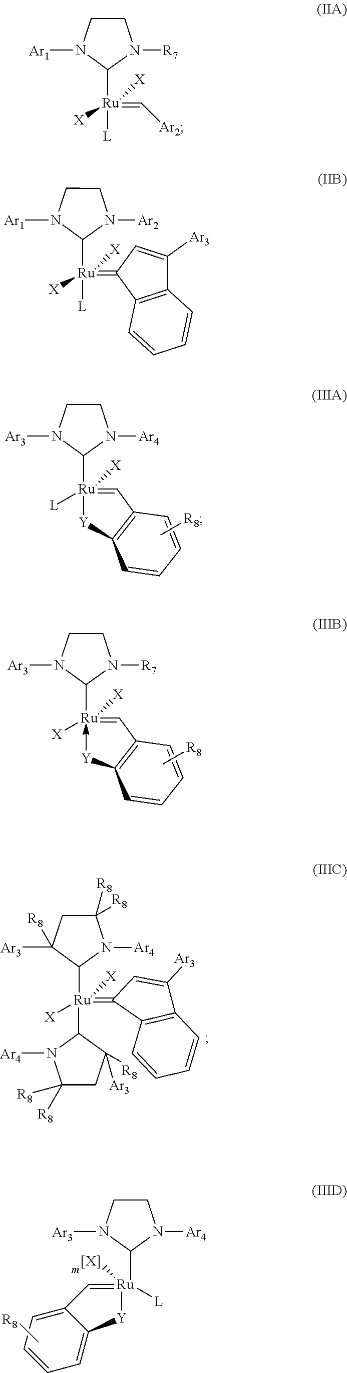

As preferable embodiment of this invention, the organo-ruthenium compound is selected from the group consisting of a compound of formula (IIB), a compound of formula (IIIA), a compound of formula (IIIB), and a compound of formula (IIID). As more preferable embodiment of this invention, the organo-ruthenium compound is a compound of formula (IIIA), or a compound of formula (IIID).

The metal of ruthenium of formula (IIA), formula (IIB), formula (IIIA), formula (IIIB), formula (IIIC), or formula (IIID) can be optionally replaced by osmium or palladium. It is further preferable embodiment of the invention that the metal of (b) metal catalyst is ruthenium.

X is each independently selected from the group consisting of chlorine, bromine, iodine, —ORₐ, —O(CO)Rₐ, —S(Rₐ)₂, —OSO₂Rₐ and —N(Rₐ)₂. As one preferable embodiment, X is each independently selected from the group consisting of chlorine, bromine, iodine, —S(Rₐ)₂, —OSO₂Rₐ, and —N(Rₐ)₂. As one more preferable embodiment, X is each independently selected from the group consisting of iodine, —S(Rₐ)₂, and —N(Rₐ)₂.
Rₐ is each independently selected from the group consisting of single bond, C₁₋₁₂ alkyl, C₃₋₁₂ cycloalkyl, C₆₋₁₄ aryl and ═CH(Rₐ′). As one preferable embodiment, Rₐ is each independently selected from the group consisting of single bond, C₁₋₄ alkyl, phenyl, and ═CH(Rₐ′). As one more preferable embodiment, Rₐ is each independently selected from the group consisting of single bond, phenyl, and ═CH(Rₐ′).

Any combination of two combination Rₐs can bond each other.
Rₐ′ is a single bond which binds to Rₐ or L (preferably to L).
Y is selected from the group consisting of O, S and NCOCF₃ (preferably O and S; more preferably O).
Y′ is selected from the group consisting of OR₉, SR₉ and —N═CHC(O)O(C₁₋₆ alkyl).
R₉ is selected from the group consisting of methyl, ethyl, linear or branched C₁₋₆ alkyl, C₆₋₁₀ aryl, methoxy, ethoxy, linear or branched C₁₋₆ alkoxy, C₆₋₁₀ aryloxy and —OCH(CH₃)C(O)N(CH₃)(OCH₃). Preferable embodiment of R₉ is selected from the group consisting of methyl, ethyl, linear or branched C₃₋₆ alkyl, C₆₋₁₀ aryl, methoxy, ethoxy, linear or branched C₃₋₆ alkoxy, C₆₋₁₀ aryloxy and —OCH(CH₃)C(O)N(CH₃)(OCH₃).
L is selected from the group consisting of pyridine, PR₃, 0=PR₃ and —O—R₃ (preferably PR₃ and —O—R₃).
R₃ is independently selected from the group consisting of isopropyl, sec-butyl, tert-butyl, cyclohexyl, bicyclo C₅₋₁₀ alkyl, phenyl, benzyl, isopropoxy, sec-butoxy, tert-butoxy, cyclohexyloxy, phenoxy and benzyloxy (preferably isopropyl, sec-butyl, tert-butyl, cyclohexyl, bicyclo C₅₋₁₀ alkyl, phenyl, benzyl, isopropoxy, sec-butoxy, tert-butoxy, cyclohexyloxy, phenoxy and benzyloxy; more preferably cyclohexyl, and phenyl).

Any one of X and L can form an anionic ligand of the formula X-L.
R₇ is selected from the group consisting of isopropyl, sec-butyl, tert-butyl, substituted or unsubstituted cyclohexyl, substituted or unsubstituted phenyl, substituted or unsubstituted biphenyl and substituted or unsubstituted naphthyl (preferably isopropyl, sec-butyl, tert-butyl, cyclohexyl, substituted phenyl, and substituted naphthyl; more preferably cyclohexyl, and substituted phenyl, and substituted naphthyl).
R₈ is selected from the group consisting of hydrogen, chlorine, methyl, ethyl, linear or branched C₁₋₆ alkyl, C₆₋₁₀ aryl, methoxy, ethoxy, linear or branched C₁₋₆ alkoxy, C₆₋₁₀ aryloxy, —NHCO(C₁₋₆)alkyl, —NHCO-perfluoro (C₁₋₆)alkyl, —SO₂N((C₁₋₆)alkyl)₂ and —NO₂. It is one preferred embodiment of this invention that R₈ is selected from the group consisting of hydrogen, chlorine, methyl, ethyl, phenyl, methoxy, ethoxy, and —NO₂. More preferably R₈ is hydrogen.
Ar₁, Ar₂ Ar₃ and Ar₄ are each independently selected from the group consisting of substituted or unsubstituted phenyl, substituted or unsubstituted biphenyl and substituted or unsubstituted naphthyl (preferably substituted or unsubstituted phenyl; more preferably substituted phenyl). As one embodiment of this invention, each Ar₁, Ar₂ Ar₃ and Ar₄ independently preferably has 1-3 substituent(s) on the selected group (more preferably 1 or 3 substituents; further preferably 3 substituents; alternatively further preferably 1 substituent).

When above described groups have substituent(s), substituents are each independently selected from the group consisting of methyl, ethyl, iso-propyl, tert-butyl, phenyl and OSi(SiMe₃)₃ (preferably methyl, ethyl, and iso-propyl; more preferably methyl, and iso-propyl). In here, “Me” of “OSi(SiMe₃)₃” is methyl.
m is an integer of 1, 2 or 3 (preferably 1 or 2; more preferably 1). It is also one another more preferable embodiment of this invention that m is 2.

Though there's no intent to limit the scope of this invention, exemplified compounds of the (b) latent organo-transition metal catalyst can be described as below.

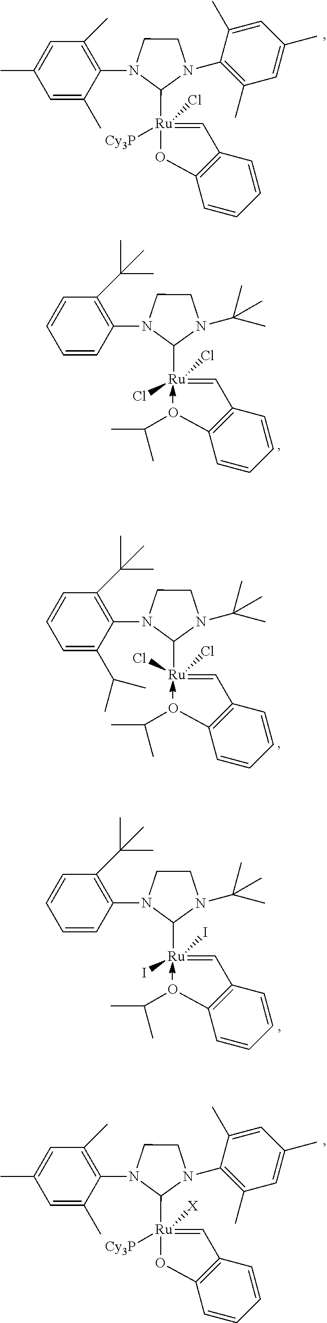

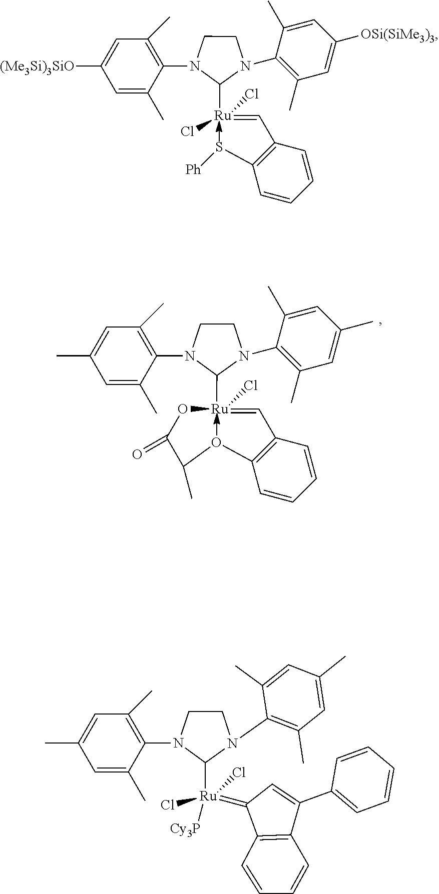

The content of the (b) latent organo-transition metal catalyst is 0.0001-1.0 mass % (preferably 0.001-0.5 mass %; more preferably 0.005-0.4 mass %; further preferably 0.010-0.10 mass %) based on the composition.

### [(c) Compound Capable of Releasing a Bronsted Acid]

The composition of this invention comprises (c) a compound capable of releasing a Bronsted acid when subjected to photolytic conditions.

As one embodiment of this invention, the (c) compound is represented by the below formula (V).

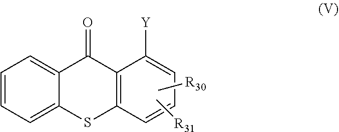

Y is halogen (preferably chlorine, bromine, or iodine; more preferably chlorine).
R₃₀ and R₃₁ are each independently selected from the group consisting of hydrogen, methyl, ethyl, linear or branched C₃₋₁₂ alkyl, C₃₋₁₂ cycloalkyl, C₆₋₁₂ bicycloalkyl, C₇₋₁₄ tricycloalkyl, C₆₋₁₀ aryl, C₆₋₁₀ aryl C₁₋₃ alkyl, C₁₋₁₂ alkoxy, C₃₋₁₂ cycloalkoxy, C₆₋₁₂ bicycloalkoxy, C₇₋₁₄ tricycloalkoxy, C₆₋₁₀ aryloxy C₁₋₃ alkyl and C₆₋₁₀ aryloxy.
R₃₀ is preferably selected from the group consisting of hydrogen methyl, ethyl, iso-propyl, n-propyl, phenyl, methoxy, ethoxy, iso-propoxy, n-propoxy, and phenoxy (more preferably hydrogen methyl, ethyl and t-butyl; further preferably hydrogen, and t-butyl; further more preferably hydrogen).
R₃₁ is preferably selected from the group consisting of methyl, ethyl, iso-propyl, n-propyl, phenyl, methoxy, ethoxy, iso-propoxy, n-propoxy, and phenoxy (more preferably methyl, ethyl, n-propyl, methoxy, ethoxy, n-propoxy, and phenoxy; further preferably ethoxy, and n-propoxy; further more preferably n-propoxy).

Though there's no intent to limit the scope of this invention, exemplified compounds of the (c) compound capable of releasing a Bronsted acid when subjected to photolytic conditions can be described as below.

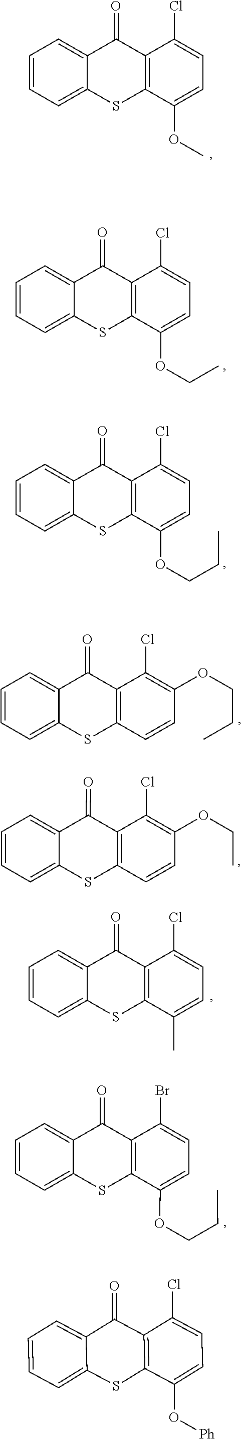

The content of the (c) compound capable of releasing a Bronsted acid is 0.0001-1.0 mass % (preferably 0.001-0.5 mass %; more preferably 0.01-0.40 mass %; further preferably 0.02-0.10 mass %) based on the composition.

### [(d) Absorber Compound]

The composition of this invention comprises (d) an absorber compound having a maximum absorption at a wavelength between 280-410 nm. It is one embodiment of this invention that the (d) absorber compound has a maximum absorption wavelength preferably between 300-410 nm (more preferably 350-410 nm).

Light absorption characteristic can be measured by known method. For example, the (d) absorber compound is dissolved in a non-polar organic solvent (e.g., 1-Heptyl-2-norbornene), and the solution is evaluated regarding each light source (e.g., UV) absorption spectrum using known spectroscopy equipment.

The (d) absorber compound works to block UV by a mechanism of “Exited state intramolecular proton transfer (ESIPT)”; and/or the (d) absorber compound is excited by electronic field when formed (preferably by deposition) to the layer.

It is one preferable embodiment of this invention that the (d) absorbers compound works to block UV by a mechanism of ESIPT.

The (d) absorber compound can have hydroxyl and/or methoxy (preferably hydroxyl or methoxy; more preferably hydroxyl).

As one embodiment of the invention that the (d) absorber compound is preferably represented by a formula selected from the group consisting of the following formula (d-1), (d-2) and (d-3) (more preferably (d-1), and (d-2); further preferably (d-1)). Such (d) absorber compound is preferable to work ESIPT mechanism in the layer formed by the composition of this invention. Each formula is described in detailed below.

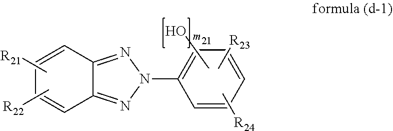

R₂₁ and R₂₂ are each independently hydrogen, linear or branched C₁₋₅ alkyl or C₆₋₁₀ aryl (preferably hydrogen, or linear C₁₋₅ alkyl).

Optionally C₁₋₅ alkyls of R₂₁ and R₂₂ can bond each other to make a saturated or unsaturated ring. As one embodiment of this invention, C₁₋₅ alkyls of R₂₁ and R₂₂ preferably bond each other to make a saturated ring (more preferably to make a cyclopentane). Optionally one or more of methylene of such saturated ring can be each independently replaced with —(C═O)— or —NR₂₅—. As one embodiment of this invention, preferably two or three of methylene of such saturated ring each independently replaced with —(C═O)— or —NR₂₅—.

Formula (d-1) can be formula (d-1-1) described below. When read (d-1-1) from formula (d-1), C₁₋₅ alkyls of R₂₁ and R₂₂ bond each other to make a saturated ring (cyclopentane). 2 methylenes in the cyclopentane are replaced with —(C═O)— linkers. 1 methylene in the cyclopentane is replaced with —NR₂₅—.

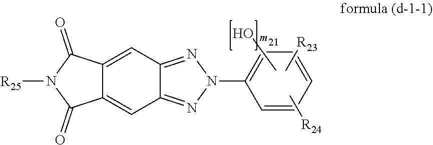

R₂₅ is each dependently hydrogen, linear or branched C₁₋₅ alkyl or C₆₋₁₀ aryl (preferably hydrogen, methyl, ethyl, iso-propyl, n-propyl, n-butyl, t-butyl, or phenyl; more preferably hydrogen, methyl, n-propyl, n-butyl, or phenyl; further preferably n-butyl).
m₂₁ is an integer of 1-3 (preferably 1 or 2; more preferably 1).
R₂₃ and R₂₄ are each independently C₁₋₁₀ alkyl, C₆₋₁₈ aryl, C₆₋₁₂ aryl C₁₋₅ alkyl, or C₁₋₅ alkyl C₆₋₁₂ aryl (preferably C₄₋₈ alkyl, phenyl, and phenyl C₁₋₃ alkyl; more preferably C₅₋₈ alkyl, and phenyl C₁₋₃ alkyl).

Alkyl portion of R₂₃ and R₂₄ can be linear or branched each independently (preferably whole or part of such alkyl portion is branched).

Optionally methylene of alkyl portion of R₂₃ and R₂₄ can be replaced with —CO—, —O—, or —COO— (preferably —COO—).

Though there's no intent to limit the scope of this invention, exemplified compounds of formula (d-1) can be described as below.

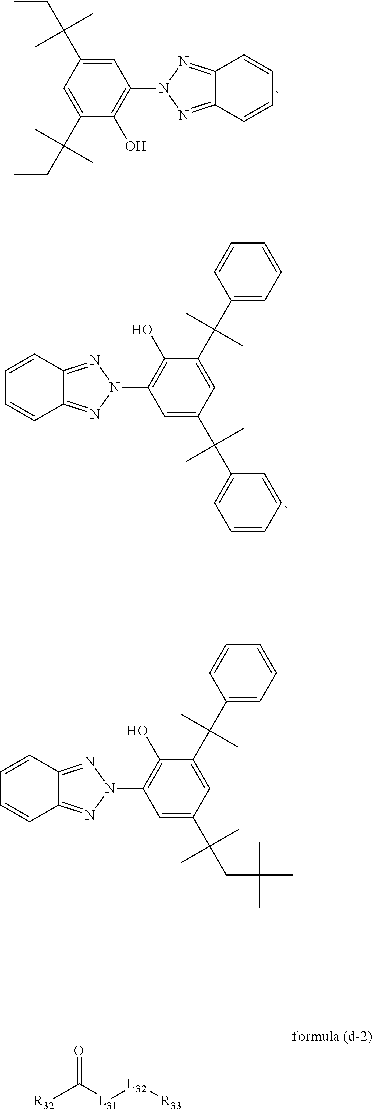

R₃₂ and R₃₃ are each independently C₁₋₂₁ hydrocarbon groups (preferably linear or branched C₁₋₂₁ alkyl; more preferably linear or branched C₁₋₁₀ alkyl). C₁₋₂₀ hydrocarbon groups of R₃₂ and R₃₃ can optionally form saturated or unsaturated ring (preferably benzene ring). The compound represented by formula (d-2) can have one or more portion of carbon-carbon single bond replaced with carbon-carbon double bond. Preferably R₃₂ and R₃₃ can have one or more portion of carbon-carbon single bond replaced with carbon-carbon double bond. Methylene portion of the R₃₂ can be replaced with —O— or —CO—.
L₃₁ is a C₁₋₁₂ hydrocarbon linker (preferably linear or branched C₁₋₆ alkylene; more preferably linear or branched C₁₋₄ alkylene; further preferably methylene). L₃₁ can optionally form saturated or unsaturated ring (preferably phenylene). Methylene portion of the L₃₁ optionally can be replaced with —O—. L₃₂ is —CO—, —CH₂—, or —CH(CH₃)— (preferably —CO—, or —CH(CH₃)—; more preferably —CH(CH₃)—).

At least one of methyl in the compound represented by formula (d-2) is replaced by hydroxyl or methoxy.

Though there's no intent to limit the scope of this invention, exemplified compounds of formula (d-2) can be described as below.

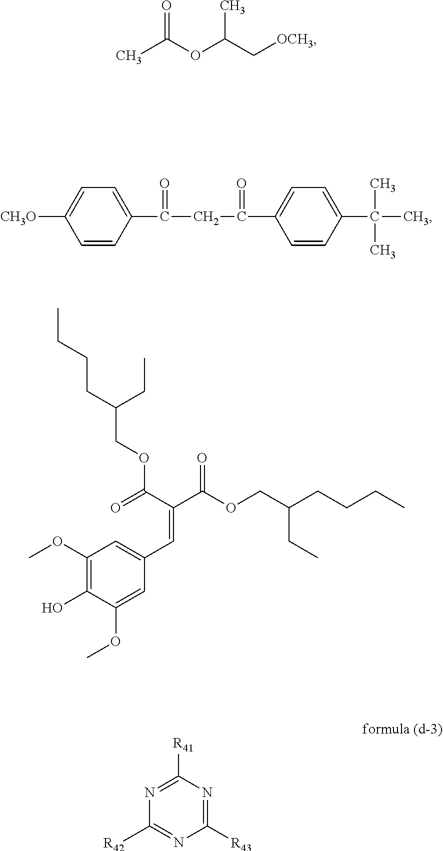

R₄₁, R₄₂ and R₄₃ are each independently C₁₋₂₀ hydrocarbon groups. C₁₋₂₀ hydrocarbon groups of R₄₁, R₄₂ or R₄₃ can optionally form saturated or unsaturated ring (preferably benzene ring). Methylene portion of the R₄₁, R₄₂ or R₄₃ can optionally be replaced with —O—.

At least one of methyl in the compound represented by formula (d-3) is replaced by hydroxyl or methoxy.

Though there's no intent to limit the scope of this invention, exemplified compound of formula (d-3) can be described as below.

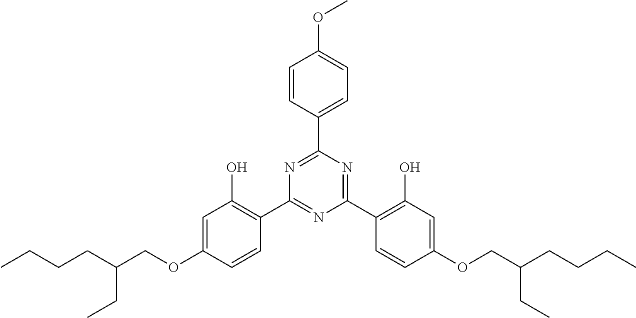 [SMILES: CCCCC(CC)COc1ccc(-c2nc(-c3ccc(OC)cc3)nc(-c3ccc(OCC(CC)CCCC)cc3O)n2)c(O)c1]

(d) absorber compounds can be obtained by market. Examples of commercially available (d) absorbers can be selected from the group consisting of Tinuvin328, Tinuvin477, Tinuvin900, Tinuvin928, Tinuvin970, Tinuvin384, Eusolex 9020, Oxynex ST, Eusolex S, BL1226, BL1337 (Jade New Material), FDB-009 (Yamada Chemical), LOTSORB B series (Jiangxi Lotchem), LA-F70 (Adeka Fine Chemicals) and any combination of any of them.

As another preferable embodiment of this invention, (d) absorber compound can have a character to be excited by electronic field when formed to the layer. For example, chemical compounds used in OLED have such character. It is preferable embodiments of such (d) absorber compounds that those can be used in emission layer (EML, as host or dopant), hole transporting layer (HTL), hole injection layer (HIL), electron transporting layer (ETL), or electron injection layer (EIL) in OLED. Herein later, such (d) absorber compounds which can exhibit property(s) for OLED are denoted as “(d) absorber compound with OLED property”. It is more preferable embodiments of such (d) absorber compounds that those can be used in HTL or HIL in OLED. It is further preferable embodiment of such (d) absorber compounds that it can be used in HTL in OLED.

Such layer formation can be done by coating or deposition (preferably vacuumed deposition).

The preferred examples of (d) absorber compounds with OLED property can hole-injection and/or hole-transport properties when formed in layer in OLED. Those include, for example, triarylamines, benzidines, tetraaryl-para-phenylenediamines, triarylphosphines, phenothiazines, phenoxazines, dihydrophenazines, thianthrenes, dibenzo-para-dioxins, phenoxathiynes, carbazoles, azulenes, thiophenes, pyrroles and furans as well as their derivatives and further O-, S- or N-containing heterocycles having a high HOMO (HOMO=highest occupied molecular orbital).

As compounds which have hole-injection and/or hole-transport properties, particular mention may be made of phenylenediamine derivatives (U.S. Pat. No. 3,615,404), arylamine derivatives (U.S. Pat. No. 3,567,450), amino-substituted chalcone derivatives (U.S. Pat. No. 3,526,501), styrylanthracene derivatives (JP-A-56-46234), polycyclic aromatic compounds (EP 1009041), polyarylalkane derivatives (U.S. Pat. No. 3,615,402), fluorenone derivatives (JP-A-54-110837), hydra-zone derivatives (U.S. Pat. No. 3,717,462), acylhydrazones, stilbene derivatives (JP-A-61-210363), silazane derivatives (U.S. Pat. No. 4,950,950), polysilanes (JP-A-2-204996), aniline copolymers (JP-A-2-282263), thiophene oligomers (JP Heisei 1 (1989)211399), polythiophenes, poly (N-vinylcarbazole) (PVK), polypyrroles, polyanilines and other electrically conducting macromolecules, porphyrin compounds (JP-A-63-2956965, U.S. Pat. No. 4,720,432), aromatic dimethylidene-type compounds, carbazole compounds, such as, for example, CDBP, CBP, mCP, aromatic tertiary amine and styrylamine compounds (U.S. Pat. No. 4,127,412), such as, for example, triphenylamines of the benzidine type, triphenylamines of the styrylamine type and triphenylamines of the diamine type. It is also possible to use arylamine dendrimers (JP Heisei 8 (1996) 193191), monomeric triarylamines (U.S. Pat. No. 3,180,730), triarylamines containing one or more vinyl radicals and/or at least one functional group containing active hydrogen (U.S. Pat. Nos. 3,567,450 and 3,658,520), or tetraaryldiamines (the two tertiary amine units are connected via an aryl group). More triarylamino groups may also be present in the molecule. Phthalocyanine derivatives, naphthalocyanine derivatives, butadiene derivatives and quinoline derivatives, such as, for example, dipyrazino[2,3-f: 2′,3′-h] quinoxalinehexacarbo-nitrile, are also suitable.

Preference is given to aromatic tertiary amines containing at least two tertiary amine units (US 2008/0102311 A1, U.S. Pat. Nos. 4,720,432 and 5,061,569), such as, for example, NPD (α-NPD=4,4′-bis[N-(1-naphthyl)-N-phenylamino] biphenyl) (U.S. Pat. No. 5,061,569), TPD 232 (═N,N′-bis-(N,N′-diphenyl-4-aminophenyl)-N,N-diphenyl-4,4′-diamino-1,1′-biphenyl) or MTDATA (MTDATA or m-MTDATA=4,4′,4″-tris[3-methylphenyl)phenylamino] triphenylamine) (JP-A-4-308688), TBDB (═N,N,N′,N′-tetra(4-biphenyl)diaminobiphenylene), TAPC(=1,1-bis(4-di-p-tolylaminophenyl)cyclohexane), TAPPP (=1,1-bis(4-di-p-tolylaminophenyl)-3-phenylpropane), BDTAPVB (=1,4-bis[2-[4-[N,N-di(p-tolyl)amino] phenyl] vinyl] benzene), TTB (═N,N,N′,N′-tetra-p-tolyl-4,4′-diaminobiphenyl), TPD (=4,4′-bis[N-3-methylphenyl]-N-phenylamino)-biphenyl), N,N,N′,N′-tetraphenyl-4,4″-diamino-1,1′,4′,1″,4″,1″-quaterphenyl, likewise tertiary amines containing carbazole units, such as, for example, TCTA (=4-(9H-carbazol-9-yl)-N,N-bis[4-(9H-carbazol-9-yl)phenyl]-benzenamine). Preference is likewise given to hexaazatriphenylene compounds in accordance with US 2007/0092755 A1 and phthalocyanine derivatives (for example H2Pc, CuPc (=copper phthalocyanine), CoPc, NiPc, ZnPc, PdPc, FePc, MnPc, ClAlPc, ClGaPc, ClInPc, ClSnPc, Cl₂SiPc, (HO)AlPc, (HO)GaPc, VOPc, TiOPc, MoOPc, GaPc-O-GaPc).

More preferable examples of (d) absorber compounds with OLED property can be described as below formulae (TA-1) to (TA-16), which are disclosed in EP 1162193 B1, EP 650 955 B1, Synth. Metals 1997, 91 (1-3), 209, DE 19646119 A1, WO 2006/122630 A1, EP 1 860 097 A1, EP 1834945 A1, JP 08053397 A, U.S. Pat. No. 6,251,531 B1, US 2005/0221124, JP 08292586 A, U.S. Pat. No. 7,399,537 B2, US 2006/0061265 A1, EP 1 661 888 and WO 2009/041635. The said compounds of the formulae (TA-1) to (TA-16) may also be substituted.

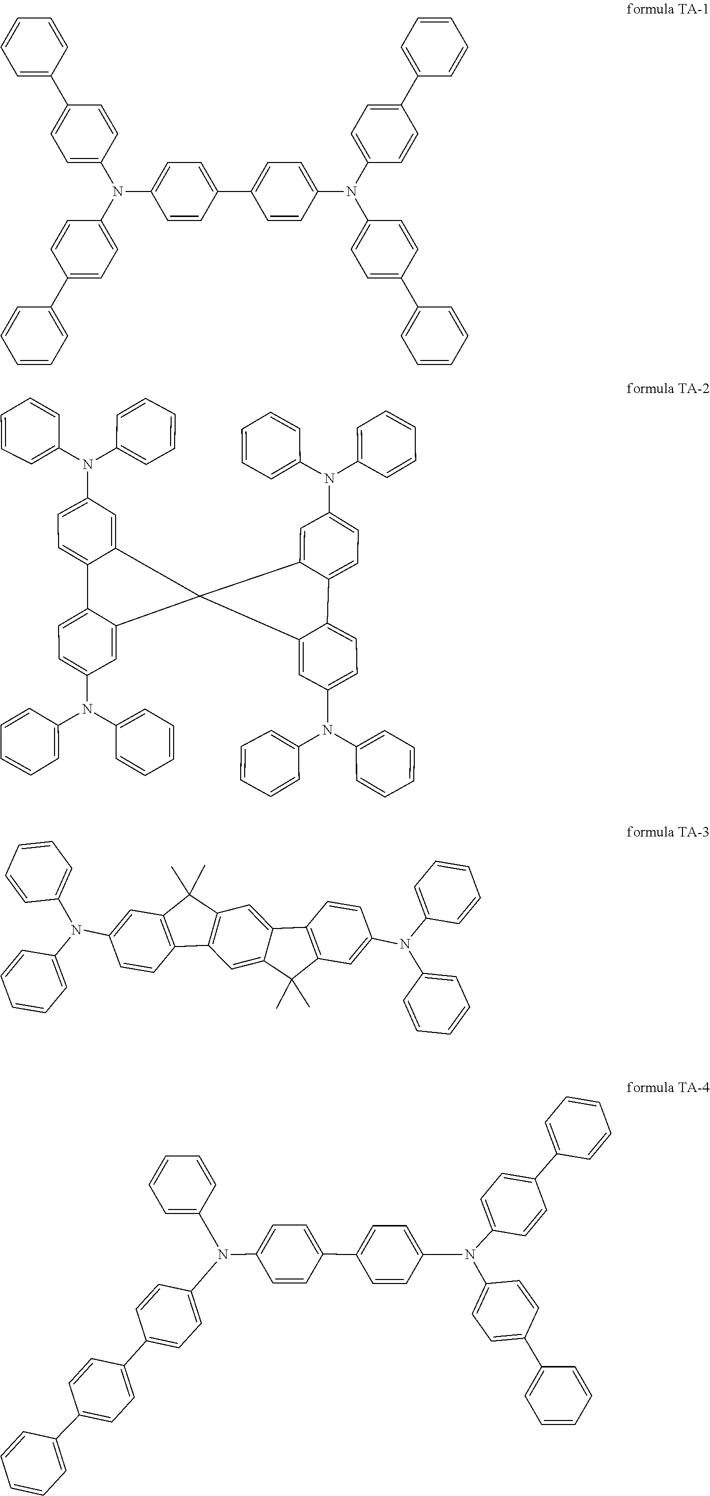

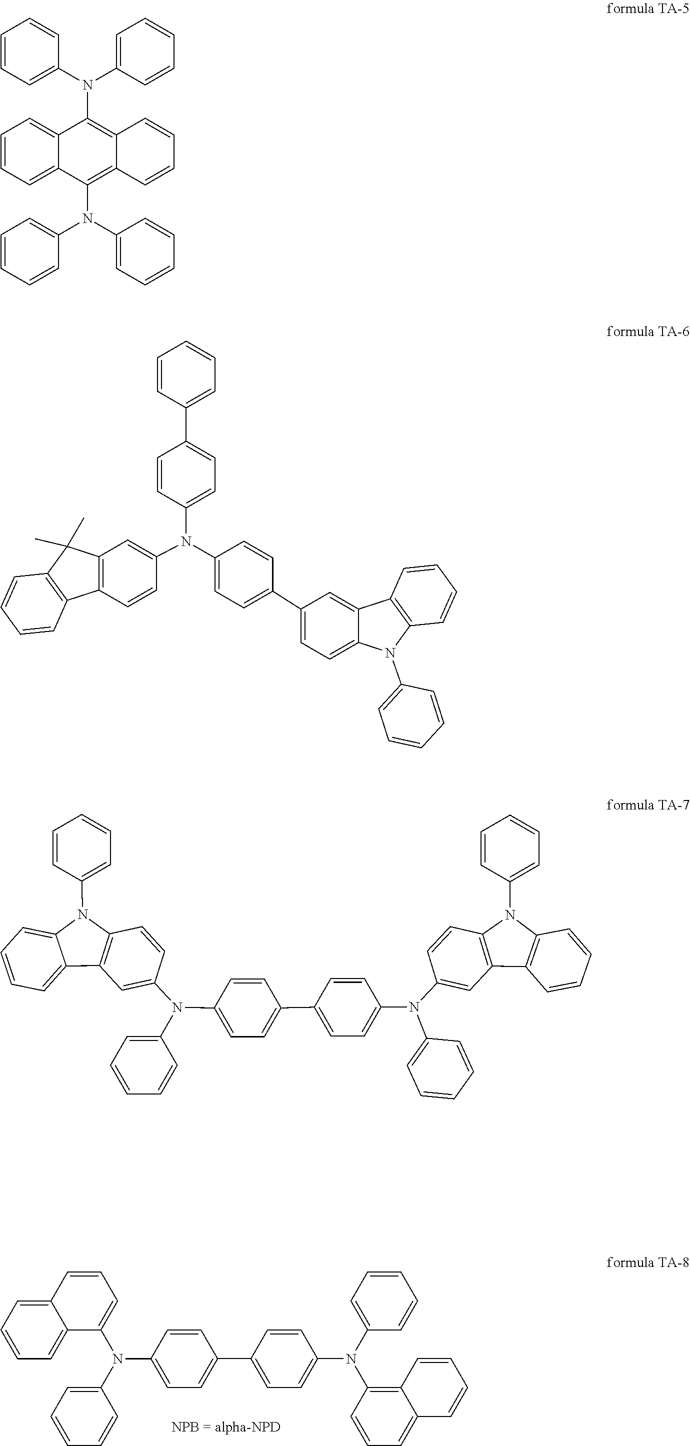 [SMILES: c1ccc(N(c2ccccc2)c2c3ccccc3c(N(c3ccccc3)c3ccccc3)c3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(N(c2ccc(-c3ccc(N(c4ccccc4)c4cccc5ccccc45)cc3)cc2)c2cccc3ccccc23)cc1]

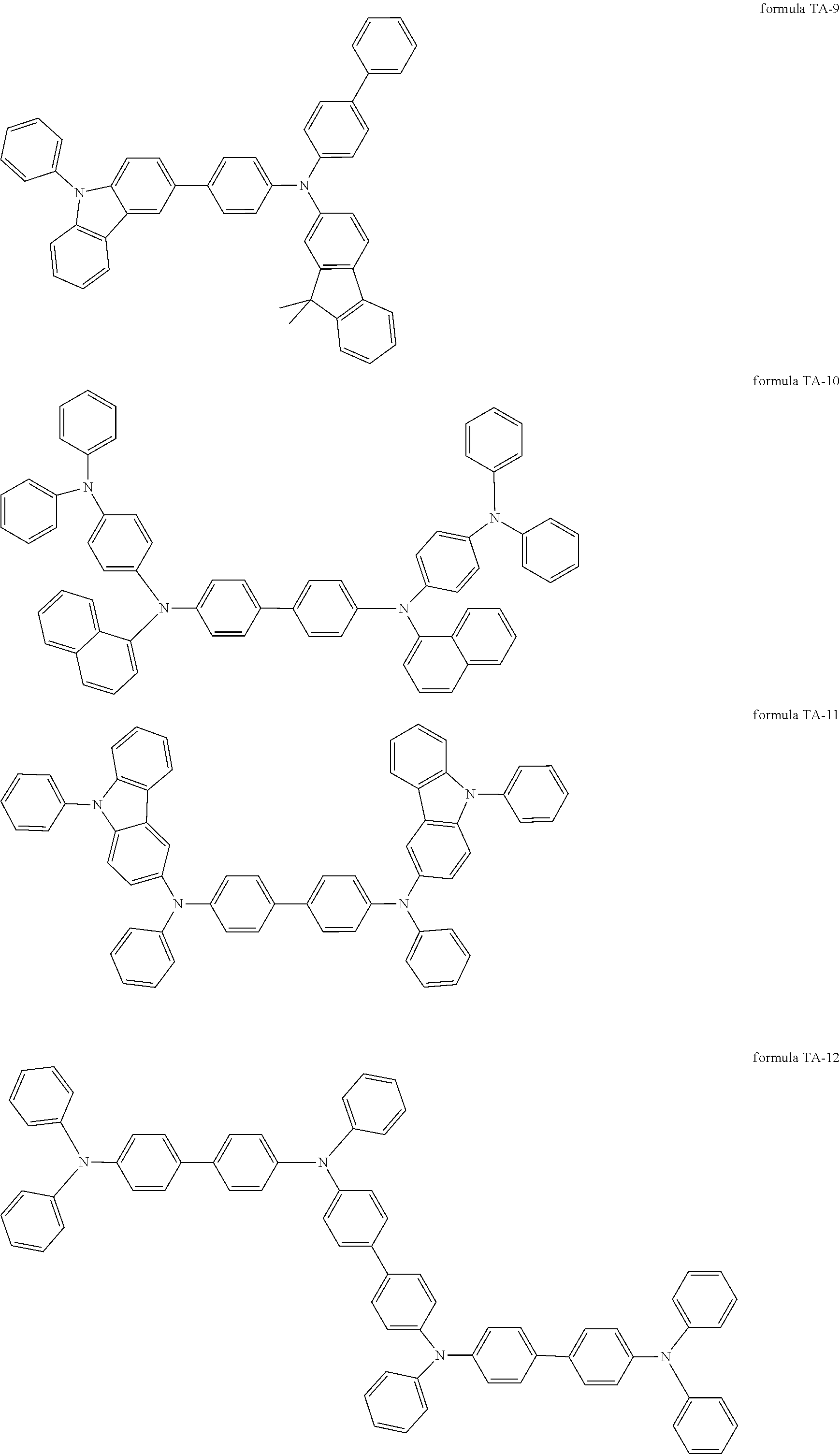

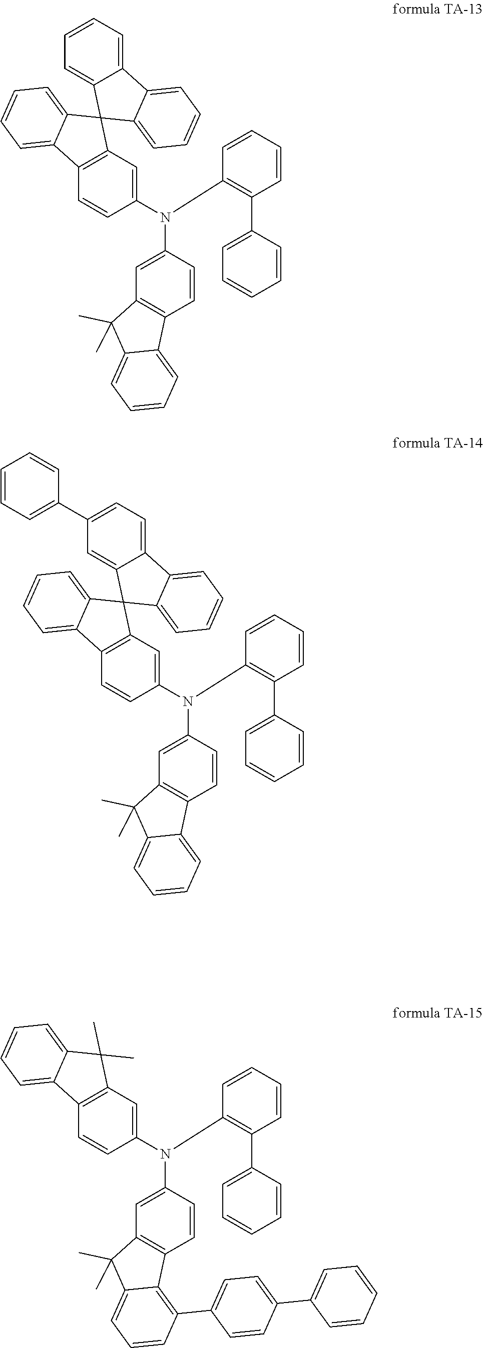 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21 ; CC1(C)c2ccccc2-c2ccc(N(c3ccc4c(c3)C(C)(C)c3cccc(-c5ccc(-c6ccccc6)cc5)c3-4)c3ccccc3-c3ccccc3)cc21]

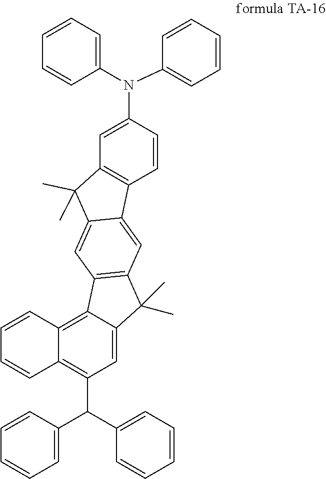 [SMILES: CC1(C)c2cc(N(c3ccccc3)c3ccccc3)ccc2-c2cc3c(cc21)-c1c(cc(C(c2ccccc2)c2ccccc2)c2ccccc12)C3(C)C]

Further compounds which can be employed as (d) absorber compounds with OLED property are described in EP 0891121 A1, EP 1029909 A1, and US 2004/0174116 A1.

These arylamines and heterocycles which are generally employed as (d) absorber compounds with OLED property preferably result in a HOMO in the layer formed by them of greater than-5.8 eV (vs. vacuum level) (more preferably greater than-5.5 eV).

As one embodiment of the composition of this invention, the content of the (d) absorber compound is 0.5-15 mass % (preferably 1-15 mass %; more preferably 2-10 mass %; further preferably 2-6 mass %) based on the composition. For clarity, when the composition comprises plural species of (d) absorber compounds, the said contents is the sum of these (d) absorber compounds.

### [Additive]

The composition of this invention can further comprise additive. Here, additive is different from the components described above. The additive can be selected from the group consisting of anti-oxidant, synergist, viscosity modifier, binder, solvent, other absorber and any combination of any of these. In here, other absorber means compound absorb light which is different from whichever compound represented by formula (d-1), (d-2) and (d-3), and whichever compound which can be excited by electronic field when formed to the layer. As the solvent, for example organic solvent is useful to dissolve certain compound whose solubility is low. Embodiments described in US2020/002466 A1 or WO2020/002277A1 can be generally employed as such additive.

As one embodiment of the composition of this invention, the content of such additive is 0-15 mass % (preferably 0.01-10 mass %; more preferably 0.1-5 mass %; further preferably 0.1-1 mass %) based on the composition. It is another preferable embodiment that the composition of this invention does not comprise such additive (0.0 mass %) based on the composition.

As one embodiment, the composition of this invention can further comprise a solvent. The solvent is preferably inorganic solvent or organic solvent (more preferably organic solvent). The content of such solvent is preferably 0.0-1.0 mass % (more preferably 0.001-0.5 mass %; further preferably 0.001-0.1 mass %; further more preferably 0.001-0.01 mass %) based on the composition. It is another preferable embodiment that the composition of this invention does not comprise such solvent (0.000 mass %) based on the composition.

### [Layer Forming]

This invention provides a method of manufacturing a polycycloolefin layer comprising below steps.
(1) preparing a base member;
(2) applying the composition of this invention above the base member; and
(3) polymerizing the (a) monomers in the composition.

The numbers in parentheses indicate the order of the steps. For example, when the steps (1), (2) and (3) are described, the order of the steps is as described above. Same to hereinafter, unless specifically described.

Here, in the present invention, the “above” includes the case where a polycycloolefin layer is formed on (direct contact with) a base member and the case where a polycycloolefin layer is formed above a base member via another layer. For example, a planarization film can be formed on a base member, and the composition of this invention can be applied on the planarization film.

In general terms the present application also relates to an electronic device, preferably an organic electronic device, comprising a base member, and a polycycloolefin layer, which may be produced in accordance with the present method as described herein.

Said base member is not particularly limited and may, in principle, be any member (for example, a substrate or a device or device component, all of which are described in the following) whereupon a polycycloolefin layer may be deposited. Without wishing to be bound by theory, this polycycloolefin layer is believed to contribute to protecting the underlying base member from water, oxygen, dust, or any other materials harmful to the underlying base member.

The base member is preferably an electronic device or a component of an electronic device, and more preferably an organic electronic device or a component of an organic electronic devices.

Examples of such base members may be selected from the group of electronic devices consisting of light emitting diodes, photovoltaic cells, photodetector cells, semiconductor devices, and thin film transistors, all of which may be organic, inorganic or hybrid.

Generally, such electronic device comprises, preferably in sequence, a first electrode, a functional layer, and a second electrode. The functional layer may, for example, be selected from the group consisting of light emitting layer, semiconductor layer, and photoactive layer.

Depending upon the architecture of the resulting electronic device, the polycycloolefin layer may be on the side of (but not necessarily directly adhered thereto) the first electrode or the second electrode.

The substrate, whether as part of a base member or in itself constituting the base member, is not particularly limited. Suitable substrates are preferably inert under use conditions. Such substrates may, for example, be flexible. Preferred examples of suitable substrate materials may be selected from polymers, glass, metals and any blend of any of these, including for example blends of more than one polymer or metal. Preferred polymeric materials include but are not limited to alkyd resins, allyl esters, benzocyclobutenes, butadiene-styrene, cellulose, cellulose acetate, epoxide, epoxy polymers, ethylene-chlorotrifluoro ethylene copolymers, ethylene-tetra-fluoroethylene copolymers, fiber glass enhanced polymers, fluorocarbon polymers, hexafluoropropylenevinylidene-fluoride copolymer, high density polyethylene, parylene, polyamide, polyimide, polyaramid, polysiloxanes (e.g. polydimethylsiloxane), polyethersulphone, polyethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, polycycloolefin, silicone rubbers, silicones, and maleimide-type resins. Of these polyethyleneterephthalate, polyimide, polycycloolefin and polyethylenenaphthalate materials are more preferred. Additionally, for some embodiments of the present invention the substrate can be any suitable material, for example a polymeric material, metal or glass material coated with one or more of the above listed materials or coated with one or more metal, such as for example titanium. It will be understood that in forming such a substrate, methods such as extruding, stretching, rubbing or photochemical techniques can be employed to provide a homogeneous surface for device fabrication. Alternatively, the substrate can be a polymeric material, metal or glass coated with one or more of the above polymeric materials.

In the step (2) of this invention, the measure of “applying” the composition is preferably selected from the group consisting of deposition, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating and pad printing (more preferably deposition, spin coating, ink jet printing or nozzle printing; further preferably spin coating, and ink jet printing; further more preferably ink jet printing).

In the step (3) of this invention, the (a) monomers are polymerized to be a polycycloolefin layer. The measure of “polymerizing” in the step (3) is performed by irradiation and/or heat (preferably irradiation). As above irradiation, wavelength having 260-430 nm peak top wavelength can be preferably used (more preferably 350-410 nm peak top; further preferably 380-400 nm peak top). UV irradiation is one preferable embodiment of such irradiation. The atmosphere of such irradiation can be selected from the known conditions such like that air atmosphere, nitrogen, and mixture of them. Temperature can be controlled as know conditions such like that 20-27° C. (preferably 25-27° C.).

As mentioned above, heat treatment by applying increased temperature to the composition above the base member is one embodiment of this invention. 50-150° C. (preferably 70-120° C.) is one embodiment of such condition. 10-180 minutes (preferably 10-60 minutes) is one embodiment of such condition. The atmosphere of such heat treatment can be selected from the known conditions such like that air atmosphere, nitrogen, and mixture of them. Temperature can be controlled as know conditions such like that 20-27° C. (preferably 25-27° C.).

By using the composition of this invention, it's possible to form a substantially transparent layer when exposed to suitable radiation. The polycycloolefin polymer manufactured by methods described in this specification can be the substantially transparent layer. The suitable radiation source can be a natural light, or artificial light (e.g., LED light). The substantially transparent layer can have an average transmission of preferably 80-99.9% (more preferably 90-99.9%; further preferably 95-99.9%; further more preferably 97-99.9%) of the 450-800 nm wavelength light.

It is preferable embodiment of this invention that is most of the visible light is transmitted through the layer. Accordingly, as one embodiment of this invention, such layer can have preferably 90-100% (more preferably 90-99.9%; further preferably 95-99.9%) of visible light) of visible light transmission. The visible light can be preferably 360-830 nm (more preferably 400-830 nm; further preferably 400-760 nm).

The substantially transparent layer can have an average transmission of 5-60% as of the range of 250-450 nm wavelength light. Without wishing to be bounded by theory, by including (d) absorber compound in the composition of this invention, the composition can avoid chemical process obstacles (e.g., turbidity, unsolved residue), and/or the substantially transparent layer can transmit most of visible light with reducing certain range of light. Without wishing to be bounded by theory, the substantially transparent layer can be incorporated in the light emitting device which can exhibit good visibility.

It is preferable embodiment of this invention that the substantially transparent layer has an average transmission of 5-25% as of the range of 310-360 nm wavelength light. It is preferable embodiment of this invention that the substantially transparent layer has an average transmission of 1-20% as of the range of 370-410 nm wavelength light. Transmission amount can be measured and evaluated by known methods.

It is one embodiment of this invention that the manufactured polycycloolefin layer can have a permittivity of preferably 3 or less (more preferably 2.6 or less; further preferably 2.5 or less). A permittivity of the polycycloolefin layer can be evaluated by known methods. Without wishing to be bound by theory, the polycycloolefin layer having above permittivity can exhibit characters as encapsulation layer or insulation layer.

As one embodiment of this invention, the polymer of polycycloolefin of this invention is formed having a weight average molecular weight (M_{w}) from 5,000 to 500,000 (more preferably 10,000 to 400,000; further preferably 20,000 to 250,000). In the present invention, Mw and Mn can be measured by the gel permeation chromatography (GPC). In this measurement, it is a preferable example to use a GPC column at 40° C., an eluent tetrahydrofuran at 0.6 mL/min and mono-dispersed polystyrene as a standard.

This invention provides a manufacturing a polycycloolefin layer, comprises above mentioned steps of (1), (2), (3) and;

(4) applying one or more additional layers above the polycycloolefin layer.

It is one embodiment of the invention that the additional layers are preferably selected from the group consisting of organic layers, inorganic layers, and hybrid layers (more preferably selected from the group consisting of an inorganic layer comprising a material selected from the group consisting of silicon oxide, silicon nitride, silicon oxynitride, aluminium oxynitride, magnesium oxide, aluminium oxide, aluminium nitride, titanium oxide, titanium nitride, tantalum oxide, tantalum nitride, hafnium oxide, hafnium nitride, zirconium oxide, zirconium nitride, cerium oxide, cerium nitride, indium oxide, tin oxide, tin nitride and any blend of any of these. Further preferably such additional layers constitute of a touch panel.

### [Device Manufacturing]

Without wishing to be bound by theory, polycycloolefin layer manufactured by the above-mentioned invention can have good property of transparency or flexibility. Including such polycycloolefin layer in an electronic device is advantageous. Also setting such polycycloolefin layer above a base member (preferably the base member is an electronic device) of this invention is advantageous.

This invention provides a method of manufacturing an electronic device comprising a method of manufacturing above mentioned polycycloolefin layer.

It is one embodiment of this invention that the electronic device is preferably a light emitting device (more preferably an organic light emitting device).

Preferably the light emitting device comprises in sequence a first electrode (more preferably anode), a light emitting layer, and a second electrode (more preferably cathode). Preferably the organic light emitting device comprises in sequence a first electrode (more preferably anode), a hole transport layer, a light emitting layer, an electron transport layer, and the second electrode (more preferably cathode).

For these further processing, known methods can be applied. For example, after forming the base member of this invention, if necessary, the base member is cut into chips, which are connected to a lead frame and packaged with resin. As another embodiment, the polycycloolefin layer according to this invention can constitute a layer of fabrication layers in a device (e.g., Lighting device).

This invention also provides an electronic device manufactured by the method described above.

The invention will now be described in more detail by reference to the following examples, which area illustrative only and do not limit the scope of the invention.

### Comparative Examples 1-3

Comparative compositions without (d) absorbers are prepared as follows. In a glass bottle, Ru—I (0.0046 g) and CPTX (0.0030 g) are dissolved in PENB (10 g) without solvent to form a clear composition.

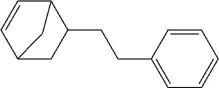 [SMILES: C1=CC2CC1CC2CCc1ccccc1]

5-phenethylbicyclo[2.2.1] hept-2-ene (PENB)

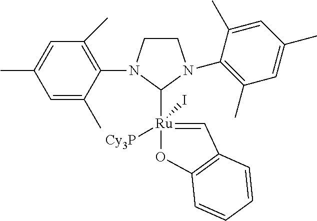

1,3-bis(2,4,6-trimethylphenylimidazolidin-2-ylidene) (tricyclohexylphospine)-(2-oxobenzylidene) ruthenium (VI) iodide (Ru—I)

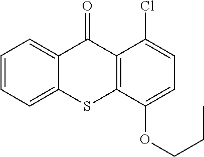 [SMILES: CCCOc1ccc(Cl)c2c(=O)c3ccccc3sc12]

1-chloro-4-propoxy-9H-thioxanthen-9-one (CPTX) Each composition is spin coated under nitrogen atmosphere on pre-cleaned Quartz substrates, to be wet films. The wet films are illuminated with UV light of 395 nm under nitrogen atmosphere to cure the film, the dose applied was in general between 0.5 and 5 J/cm². The dose used for the comparative examples is given in Table 1. The spin coating parameters are optimized to obtain 8 μm film thickness. The film thickness is determined by profilometry after curing the film and scratching with a scalpel to reference to the substrate surface.

After sample preparation, transmission spectra are registered in the wavelength range 250-800 nm.

### Working Examples 1-17

Working example compositions are prepared as follow. Except for adding (d) absorber, working example compositions are prepared in the same manner to the comparative composition 1. The amounts of (d) absorber comparting to the total of the composition are described in Table 1.

It is confirmed that working example compositions shows good transmission in visible range (450-800 nm) and UV light transmission reduction (250-450 nm).

TABLE 1
Curing UV dose and transmission data for films
prepared with and without UV blocker added.

| | | | Transmission | | |
|---|---|---|---|---|---|
| | | | | Average | Average |
| | | | Minimum | Trans- | Trans- |
| | | Dose | Trans- | mission | mission |
| | | at 395 | mission @ | 250- | 450- |
| | [wt. %] (d) | nm | wavelength | 450 nm | 800 nm |
| | absorber | [J/cm²] | [% T @ nm] | [% T] | [% T] |
| Com | — | 1 | 81.2 @ 256 | 94 | 98.8 |
| Ex. 1 | | | | | |
| Com | — | 1.5 | 81.7 @ 256 | 94.2 | 98.9 |
| Ex. 2 | | | | | |
| Com | — | 2 | 82.2 @ 256 | 94.3 | 98.9 |
| Ex. 3 | | | | | |
| Ex. 1 | 4% LA-F70 | 2 | 38.1 @ 334 | 58.8 | 99.7 |
| Ex. 2 | 8% | 1 | 42.4 @ 367 | 75.8 | 98.6 |
| | BL1337 | | | | |
| Ex. 3 | 8% | 1.5 | 42.5 @ 367 | 75.9 | 98.8 |
| | BL1337 | | | | |
| Ex. 4 | 4% FDB- | 1 | 2.0 @ 393 | 48.1 | 99.3 |
| | 009 | | | | |
| Ex. 5 | 4% FDB- | 1.5 | 1.4 @ 393 | 43.9 | 99.1 |
| | 009 | | | | |
| Ex. 6 | 2% LA-F70 | 1 | 6.0 @338 | 28.3 | 99 |
| | and 2% | | | | |
| | Tinuvin970 | | | | |
| Ex. 7 | 2% LA-F70 | 2 | 9.5 @338 | 32.5 | 98.4 |
| | and 2% | | | | |
| | Tinuvin970 | | | | |
| Ex. 8 | 1% LA-F70 | 1 | 26.9 @ 338 | 51.3 | 99 |
| | and 1% | | | | |
| | Tinuvin970 | | | | |
| Ex. 9 | 1% LA-F70 | 2 | 27.5 @ 338 | 51.8 | 99 |
| | and 1% | | | | |
| | Tinuvin970 | | | | |
| Ex. 10 | 4% | 2 | 3.3 @ 280 | 22 | 99 |
| | Tinuvin970 | | | | |
| | and 2% | | | | |
| | Tinuvin928 | | | | |
| Ex. 11 | 1.5% | 2 | 1.8 @ 340 | 28.2 | 99.3 |
| | Tinuvin970, | | | | |
| | 1.5% | | | | |
| | Tinuvin477 | | | | |
| | and | | | | |
| | 1.5% | | | | |
| | Tinuvin928 | | | | |
| Ex. 12 | 1% | 2 | 7.2 @ 356 | 38.4 | 99.3 |
| | Tinuvin970, | | | | |
| | 1% | | | | |
| | Tinuvin477 | | | | |
| | and | | | | |
| | 1% | | | | |
| | Tinuvin928 | | | | |
| Ex. 13 | 8% BL1226 | 1 | 42.5 @ 367 | 75.8 | 98.6 |
| Ex. 14 | 3% | 1 | 10.4 @ 347 | 40.2 | 98.6 |
| | Absorber 01 | | | | |
| Ex. 15 | 4% | 1 | 6.5 @ 346 | 32.7 | 98.3 |
| | Absorber 02 | | | | |
| Ex. 16 | 4% | 1 | 9.1 @ 347 | 35.9 | 98.5 |
| | Absorber 03 | | | | |
| Ex. 17 | 3% | 1 | 81.2 @255 | 91.8 | 98.7 |
| | Absorber 04 | | | | |

In above Table 1, “Com Ex.” means “Comparative example”. In above Table 1, simple “Ex.” means “Working example” and same applies in following Table.

TABLE 2
Structures of Absorber 01-04.

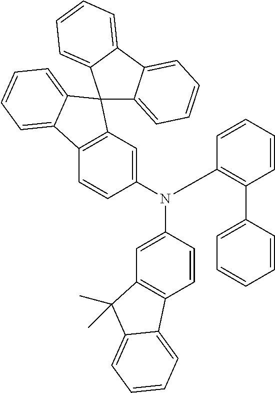 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

Absorber 01

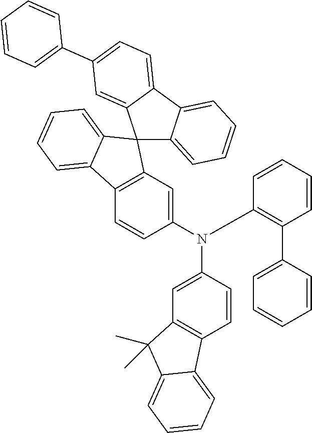 [SMILES: CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21]

Absorber 02

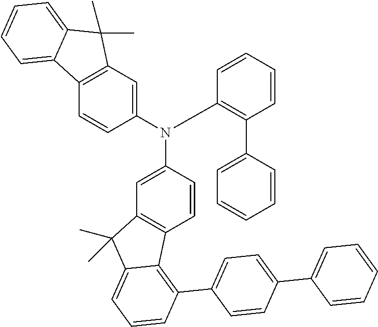 [SMILES: CC1(C)c2ccccc2-c2ccc(N(c3ccc4c(c3)C(C)(C)c3cccc(-c5ccc(-c6ccccc6)cc5)c3-4)c3ccccc3-c3ccccc3)cc21]

Absorber 03

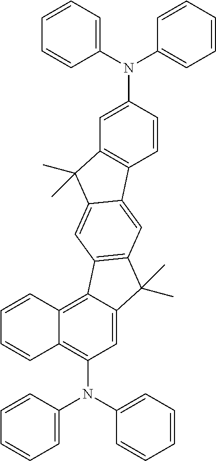 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C]

Absorber 04

### Working Examples 18-36

The solubility of the (d) absorbers is tested by each (d) absorbers dissolved in comparative example composition 1 at room temperature. This test run for a maximum of 4 weeks. Table 3 lists the compositions and their solution stability, by visual check.

TABLE 3
Formulation stability at room temperature.

| | (d) absorber | Solution stability |
|---|---|---|
| Ex. 18 | 2% Tinuvin970, | Not stable, turbid after 3 days |
| | 2% Tinuvin477 and | |
| | 2% Tinuvin928 | |
| Ex. 19 | 2% Tinuvin477 | Not stable, turbid after 3 days |
| Ex. 20 | 15% Tinuvin928 | Not fully dissolved |
| Ex. 21 | 8% BL1337 | Not fully dissolved |
| Ex. 22 | 4% LA-F70 | Not stable, turbid after 3 days |
| Ex. 23 | 4% FDB-009 | Not stable, turbid after 7 days |
| Ex. 24 | 1% LA-F70 and | Stable |
| | 1% Tinuvin970 | |
| Ex. 25 | 2% LA-F70 and | Stable |
| | 2% Tinuvin970 | |
| Ex. 26 | 4% Tinuvin970 and | Not stable, turbid after 7 days |
| | 2% Tinuvin928 | |
| Ex. 27 | 1% Tinuvin970, | Stable |
| | 1% Tinuvin477 and | |
| | 1% Tinuvin928 | |
| Ex. 28 | 1.5% Tinuvin970, | stable |
| | 1.5% Tinuvin477 and | |
| | 1.5% Tinuvin928 | |
| Ex. 29 | 8% BL1226 | Stable |
| Ex. 30 | 3% Absorber 01 | Stable |
| Ex. 31 | 4% Absorber 02 | Stable |
| Ex. 32 | 4% Absorber 03 | Stable |
| Ex. 33 | 3% Absorber 04 | stable |
| Ex. 34 | 4% Eusolex 9020 | Not dissolved |
| Ex. 35 | 4% Oxynex ST | Not stable, turbid after 2 hours |
| Ex. 36 | 4% Eusolex S | Stable |

1.-19. (canceled)

20. A composition comprising: (a) one or more monomers of formula (I); (b) a latent organo-transition metal catalyst comprising a metal selected from the group consisting of ruthenium, osmium or palladium; (c) a compound capable of releasing a Bronsted acid when subjected to photolytic conditions; and (d) an absorber compound having a maximum absorption wavelength between 280-410 nm;
wherein the formula (I) is represented by below formula; 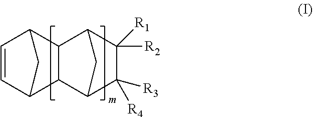
m is an integer 0, 1 or 2;
R₁, R₂, R₃ and R₄ are each independently selected from the group consisting of hydrogen, halogen, methyl, ethyl, linear or branched C₁₋₂₀ alkyl, perfluoro C₁₋₁₂ alkyl, hydroxy C₁₋₁₆ alkyl, C₃₋₁₂ cycloalkyl, C₆₋₁₂ bicycloalkyl, (CH₂)ₐ—C₆₋₁₂ bicycloalkenyl, C₇₋₁₄ tricycloalkyl, substituted or unsubstituted C₆₋₁₀ aryl, substituted or unsubstituted C₆₋₁₀ aryl C₁₋₆ alkyl, perfluoro C₆₋₁₀ aryl, perfluoro C₆₋₁₀ aryl C₁₋₃ alkyl and a group of formula (A):
—Z-Aryl (A),
wherein:
Z is a single bond or a group selected from the group consisting of: (CR₅R₆)ₐ, O(CR₅R₆)ₐ, (CR₅R₆)ₐO, (CR₅R₆)ₐ—O—(CR₅R₆)_{b}, (CR₅R₆)ₐ—O—(SiR₅R₆)_{b}, (CR₅R₆)ₐ—(CO)O—(CR₅R₆)_{b}, where a and b are integers each independently is 1 to 12;
R₅ and R₆ are each independently selected from the group consisting of hydrogen, methyl, ethyl, linear or branched C₃₋₆ alkyl, hydroxy, methoxy, ethoxy, linear or branched C₃₋₆ alkyloxy, acetoxy, C₂₋₆ acyl, hydroxymethyl, hydroxyethyl, linear or branched hydroxy C₃₋₆ alkyl, substituted or unsubstituted phenyl and substituted or unsubstituted phenoxy;
Aryl is phenyl or phenyl substituted with one or more of groups selected from the group consisting of methyl, ethyl, linear or branched C₃₋₆ alkyl, hydroxy, methoxy, ethoxy, linear or branched C₃₋₆ alkyloxy, acetoxy, C₂₋₆ acyl, hydroxymethyl, hydroxyethyl, linear or branched hydroxy C₃₋₆ alkyl, phenyl and phenoxy; and
optionally one of R₁ or R₂ taken together with one of R₃ or R₄ and the carbon atoms to which they are attached to form a C₅₋₇ carbocyclic ring optionally containing one or more double bonds.

21. The composition according to claim 20, wherein said composition forms a substantially transparent layer when exposed to suitable radiation;
wherein the substantially transparent layer has an average transmission of 80-99.9% of the 450-800 nm wavelength light; or
wherein the substantially transparent layer has an average transmission of 5-60% as of the range of 250-450 nm wavelength light.

22. The composition according to claim 20, wherein said substantially transparent layer has an average transmission 90-100% of the visible light.

23. The composition according to claim 20, wherein the (d) absorber compound works to block UV by a mechanism of Exited state intramolecular proton transfer (ESIPT); and/or
the (d) absorber compound is excited by electronic field when formed (preferably by deposition) to the layer.

24. The composition according to claim 20, wherein the (d) absorber compound has hydroxyl or methoxy; preferably the (d) absorber compound is represented by a formula selected from the group consisting of the following formula (d-1), (d-2) and (d-3); 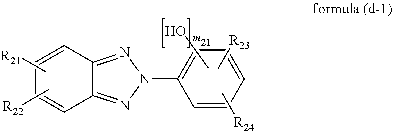
wherein
R₂₁ and R₂₂ are each independently hydrogen, linear or branched C₁₋₅ alkyl or C₆₋₁₀ aryl; optionally C₁₋₅ alkyls of R₂₁ and R₂₂ can bond each other to make a saturated or unsaturated ring; optionally one or more of methylene of such saturated ring can be each independently replaced with —(C═O)— or —NR₂₅—; where R₂₅ is each dependently hydrogen, linear or branched C₁₋₅ alkyl or C₆₋₁₀ aryl;
m₂₁ is an integer of 1-3; and
R₂₃ and R₂₄ are each independently C₁₋₁₀ alkyl, C₆₋₁₈ aryl, C₆₋₁₂ aryl C₁₋₅ alkyl, or C₁₋₅ alkyl C₆₋₁₂ aryl; where alkyl portion of R₂₃ and R₂₄ can be linear or branched each independently; and optionally methylene of alkyl portion of R₂₃ and R₂₄ can be replaced with —CO—, —O—, or —COO—; 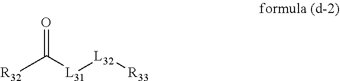
wherein
R₃₂ and R₃₃ are each independently C₁₋₂₁ hydrocarbon groups which can optionally form saturated or unsaturated ring, where optionally one or more portion of carbon-carbon single bond in the compound represented by formula (d-2) (more preferably R₃₂ or R₃₃) can be replaced with carbon-carbon double bond; optionally methylene portion of the R₃₂ can be replaced with —O— or —C(═O)—;
L₃₁ is a C₁₋₁₂ hydrocarbon linker which can optionally form saturated or unsaturated ring, where optionally methylene portion of the L₃₁ can be replaced with —O—;
L₃₂ is —CO—, —CH₂—, or —CH(CH₃)—; and
at least one of methyl in the compound represented by formula (d-2) is replaced by hydroxyl or methoxy; 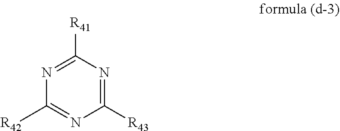
wherein
R₄₁, R₄₂ and R₄₃ are each independently C₁₋₂₀ hydrocarbon groups which can optionally form saturated or unsaturated ring, where optionally methylene portion of the R₄₁, R₄₂ or R₄₃ can be replaced with —O—; and
at least one of methyl in the compound represented by formula (d-3) is replaced by hydroxyl or methoxy.

25. The composition according to claim 20, wherein the (a) monomer of formula (I) is formula (I-a) 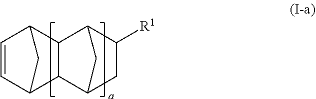
with a being 0 or 1, and R¹ being a linear or branched C₁₋₂₀ alkyl group or an unsubstituted C₆₋₁₀ aryl C₁₋₆ alkyl.

26. The composition according to claim 20, wherein the (a) monomer of formula (I) is selected from the group consisting of the following formula (I-a-01) to (I-a-21):

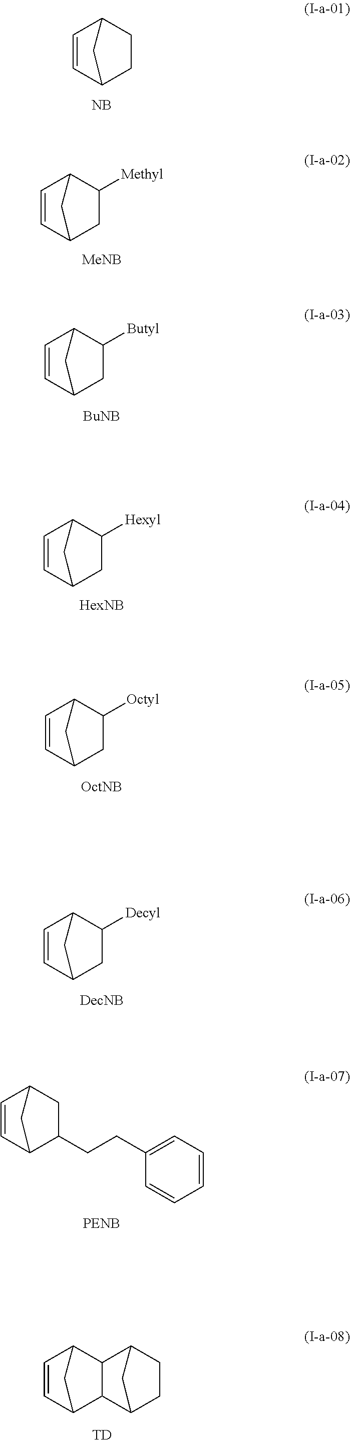

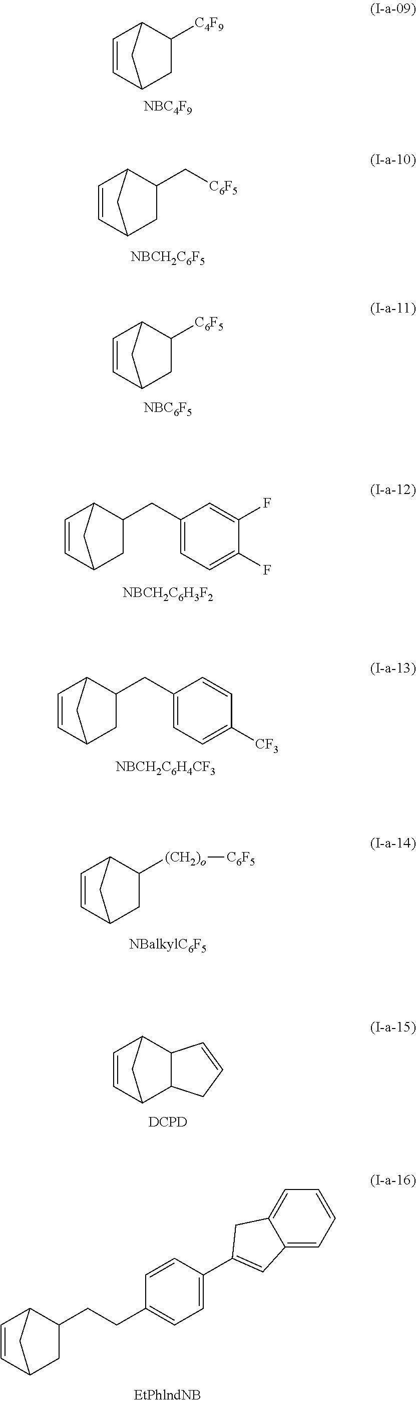

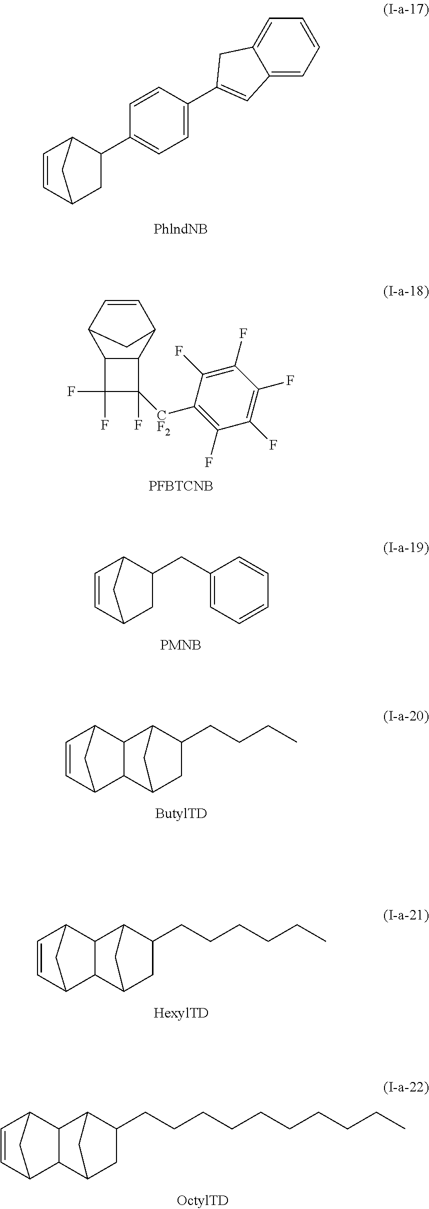

27. The composition according to claim 20, wherein the latent catalyst is an organo-ruthenium compound selected from the group consisting of a compound of formula (IIA), a compound of formula (IIB), a compound of formula (IA), a compound of formula (IIB), a compound of formula (IIIC), and a compound of formula (ID): 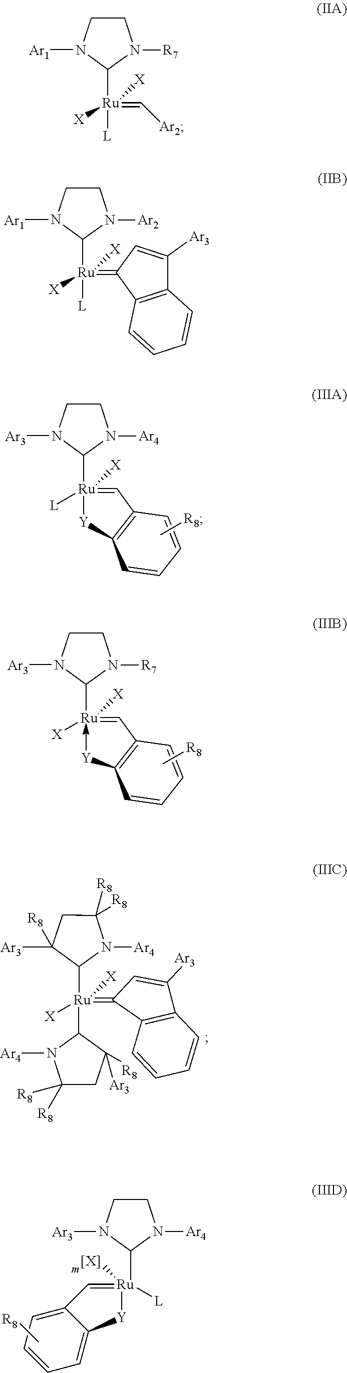
wherein:
X is each independently selected from the group consisting of chlorine, bromine, iodine, —ORₐ, —O(CO)Rₐ, —S(Rₐ)₂, —OSO₂Rₐ and —N(Rₐ)₂, where Rₐ is each independently selected from the group consisting of single bond, C₁₋₁₂ alkyl, C₃₋₁₂ cycloalkyl, C₆₋₁₄ aryl and ═CH(Rₐ′);
where any combination of two combination Rₐs can bond each other; and Rₐ′ is a single bond which binds to Rₐ or L,
Y is selected from the group consisting of O, S and NCOCF₃;
Y′ is selected from the group consisting of OR₉, SR₉ and —N═CHC(O)O(C₁₋₆ alkyl), where R₉ is selected from the group consisting of methyl, ethyl, linear or branched C₁₋₆ alkyl, C₆₋₁₀ aryl, methoxy, ethoxy, linear or branched C₁₋₆ alkoxy, C₆₋₁₀ aryloxy and —OCH(CH₃)C(O)N(CH₃)(OCH₃);
L is selected from the group consisting of pyridine, PR₃, 0=PR₃ and —O—R₃, where each R₃ is independently selected from the group consisting of isopropyl, sec-butyl, tert-butyl, cyclohexyl, bicyclo C₅₋₁₀ alkyl, phenyl, benzyl, isopropoxy, sec-butoxy, tert-butoxy, cyclohexyloxy, phenoxy and benzyloxy;
where one of X and L can form a anionic ligand of the formula X-L;
R₇ is selected from the group consisting of isopropyl, sec-butyl, tert-butyl, substituted or unsubstituted cyclohexyl, substituted or unsubstituted phenyl, substituted or unsubstituted biphenyl and substituted or unsubstituted naphthyl;
R₈ is selected from the group consisting of hydrogen, chlorine, methyl, ethyl, linear or branched C₁₋₆ alkyl, C₆₋₁₀ aryl, methoxy, ethoxy, linear or branched C₁₋₆ alkoxy, C₆₋₁₀ aryloxy, —NHCO(C₁₋₆)alkyl, —NHCO-perfluoro (C₁₋₆)alkyl, —SO₂N((C₁₋₆)alkyl)₂ and —NO₂;
Ar₁, Ar₂ Ar₃ and Ar₄ are each independently selected from the group consisting of substituted or unsubstituted phenyl, substituted or unsubstituted biphenyl and substituted or unsubstituted naphthyl;
wherein said substituents are each independently selected from the group consisting of methyl, ethyl, iso-propyl, tert-butyl, phenyl and OSi(SiMe₃)₃;
m is a integer of 1, 2 or 3.

28. The composition according to claim 20, wherein the (c) compound capable of generating Bronsted acid when subjected to photolytic conditions is of the formula (V): 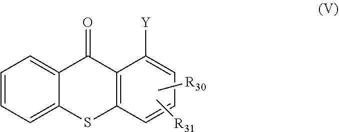
wherein
Y is halogen; and
R₃₀ and R₃₁ are each independently selected from the group consisting of hydrogen, methyl, ethyl, linear or branched C₃₋₁₂ alkyl, C₃₋₁₂ cycloalkyl, C₆₋₁₂ bicycloalkyl, C₇₋₁₄ tricycloalkyl, C₆₋₁₀ aryl, C₆₋₁₀ aryl C₁₋₃ alkyl, C₁₋₁₂ alkoxy, C₃₋₁₂ cycloalkoxy, C₆₋₁₂ bicycloalkoxy, C₇₋₁₄ tricycloalkoxy, C₆₋₁₀ aryloxy C₁₋₃ alkyl and C₆₋₁₀ aryloxy.

29. The composition according to claim 20, wherein the content of the (a) monomer is 80-99.99 mass % based on the composition;
preferably the content of the (b) latent organo-transition metal catalyst is 0.0001-1.0 mass % based on the composition;
preferably the content of the (c) compound capable of releasing a Bronsted acid is 0.0001-1.0 mass % based on the composition; or
preferably the content of the (d) absorber compound is 0.5-15 mass % based on the composition.

30. The composition according to claim 20, wherein the viscosity of the composition is 5-20 mPass at 40° C.

31. A method of manufacturing a polycycloolefin layer comprising steps of:
(1) preparing a base member;
(2) applying the composition according to claim 20 above the base member; and
(3) polymerizing the (a) monomers in the composition.

32. The method of manufacturing a polycycloolefin layer according to claim 31; where the permittivity of the polycycloolefin layer is 3 or less.

33. The method of manufacturing a polycycloolefin layer according to claim 31; wherein the measure of applying the composition in step (2) is selected from the group consisting of deposition, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating and pad printing; and
preferably deposition, ink jet printing or nozzle printing.

34. The method of manufacturing a polycycloolefin layer according to claim 31; wherein the step (3) is performed by irradiation and/or heat.

35. The method of manufacturing a polycycloolefin layer according to claim 31; further comprising the step of
(4) applying one or more additional layers above the polycycloolefin layer;
wherein the additional layers are selected from the group consisting of organic layers, inorganic layers and hybrid layers;
preferably the additional layers are selected from the group consisting of an inorganic layer comprising a material selected from the group consisting of silicon oxide, silicon nitride, silicon oxynitride, aluminum oxynitride, magnesium oxide, aluminum oxide, aluminum nitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride and any blend of any of these; or
preferably additional layers constitutes of a touch panel.

36. A method of manufacturing an electronic device comprising;
a method of manufacturing a polycycloolefin layer according to claim 31.

37. The method of manufacturing an electronic device according to claim 36, wherein the base member of the method of manufacturing a polycycloolefin is an electronic device.

38. An electronic device manufactured by the method according to claim 36.
